(19) United States
(12) Patent Application Publication
(10) Pub. No.: US 2025/0024663 A1
(43) Pub. Date: Jan. 16, 2025

(54) METHOD FOR MANUFACTURING SEMICONDUCTOR DEVICE INCLUDING BITCON AND CELLCON

(71) Applicant: MICRON TECHNOLOGY, INC., Boise, ID (US)

(72) Inventors: Vivek Yadav, Boise, ID (US); Li Wei Fang, Taichung city (TW)

(73) Assignee: MICRON TECHNOLOGY, INC., Boise, ID (US)

(21) Appl. No.: 18/747,991

(22) Filed: Jun. 19, 2024

Related U.S. Application Data
(60) Provisional application No. 63/513,254, filed on Jul. 12, 2023.

(51) Int. Cl. H10B 12/00

(52) U.S. Cl. CPC H10B 12/485; H10B 12/02

(57) ABSTRACT

According to one or more embodiments of the disclosure, a method comprises: forming a first recess for a bit line contact structure of a semiconductor device; providing a liner on a surface of the first recess; etching the linear to open at least part of a bottom of the liner, forming a second recess under the first recess; performing an epitaxial growth process through the second recess; and providing a conductive material to the first and second recesses to form at least part of the bit line contact structure.

### CROSS REFERENCE TO RELATED APPLICATION(S)

This application claims the benefit under 35 U.S.C. § 119 of the earlier filing date of U.S. Provisional Application Ser. No. 63/513,254 filed Jul. 12, 2023, the entire contents of which are hereby incorporated by reference in its entirety for any purpose.

### BACKGROUND

A semiconductor apparatus may include a semiconductor device, such as a memory device. A semiconductor device may be provided by a semiconductor chip formed on a semiconductor substrate or a semiconductor wafer. A semiconductor device may include an isolation region in a semiconductor substrate. An isolation region may define an active region. An active region may be an element formation region where elements of a semiconductor device may be formed. A semiconductor device may include a plurality of transistors. In the case of a memory device including a plurality of memory cells, for example, the memory device may include a plurality of bit lines running in parallel in a first direction and a plurality of word lines running in parallel in a second direction perpendicular to the first direction in a horizontal plane. A memory device may also include bit line contacts (or so-called bitcons) and cell contacts (or so-called cellcons).

### BRIEF DESCRIPTION OF THE DRAWINGS

FIG. 1 depicts an example of a block diagram of a memory device as a semiconductor device in a plan view according to an embodiment of the disclosure.

FIGS. 2A-2D depict an example of a dual recess formation process in a bit line contact formation area in at least part of a memory device in a cross-sectional view according to an embodiment of the disclosure.

FIGS. 3A-3D depict an example of a dual recess formation process in a cell contact formation area in at least part of a memory device in a cross-sectional view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for case of illustration. In the drawings, the dimensions and dimensional ratios of each unit do not necessarily match the actual dimensions and dimensional ratios in the embodiments.

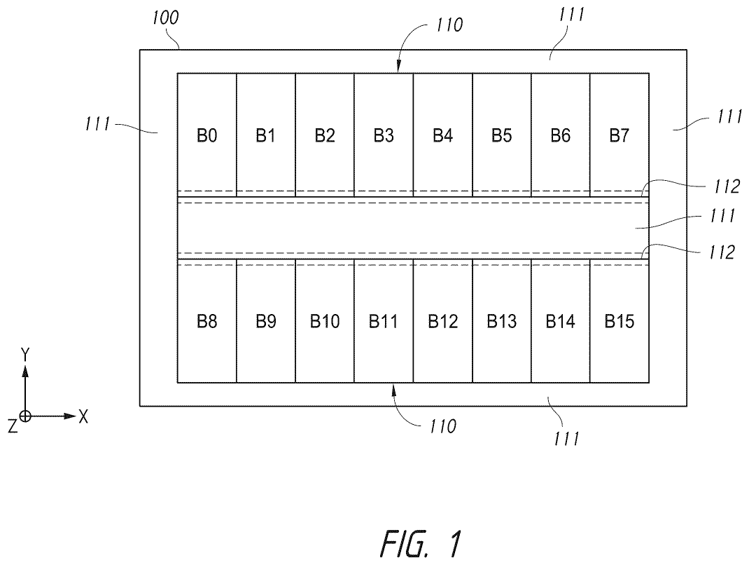

FIG. 1 depicts an example of a block diagram of a memory device 100 in a plan view according to an embodiment of the disclosure. The memory device 100 may be one example of a semiconductor device. The memory device 100 may be one example of an apparatus. The memory device 100 includes one or more memory regions (may also be referred to as cell regions) 110 and one or more periphery regions (may also be referred as peripheral regions) 111. The memory regions 110 include a plurality of memory banks of memory cells. In the example, the memory device 100 includes a pair of the memory regions 110 arranged in two rows that are extending in one horizontal direction (for example, a direction along an X-axis in the drawing) and neighboring with each other in another horizontal direction (for example, a direction along a Y-axis perpendicular to the X-axis direction in the drawing). The memory regions 110 of the pair include, respectively, a first group of memory banks BANK0-BANK7 (B0-B7) and a second group of memory banks BANK8-BANK15 (B8-B15). The memory banks in each group are arranged next to each other in the corresponding row. The memory banks may be accessed to read data from and write data to the memory cells. In the example, one periphery region 111 is provided between the memory regions 110. The periphery region 111 is adjacent to the memory regions 110 with boundaries or boundary regions 112 therebetween. Regions around the memory regions 110 may also be the periphery regions 111 including boundaries or boundary regions with the neighboring memory regions 110. Various circuits and circuit elements (for example, transistors) that are used for memory operations are included in the periphery regions 111. Such circuits and circuit elements in the periphery regions 111 are electrically connected to or electrically coupled to the memory cells in the memory regions 110 via, for example, conductive wirings or wiring layers, and conductive contacts. The number, the position, the arrangement and such of the memory regions 110 are not limited to the examples and the embodiments described herein. The number, the position, the arrangement and such of the memory banks and/or the memory cells are not limited to the examples and the embodiments described herein. The number, the position, the arrangement and such of the periphery regions 111 are not limited to the examples and the embodiments described herein. The memory regions 110 and the periphery regions 111 are formed on a semiconductor substrate or a semiconductor wafer (not separately depicted) by multiple processes of a plurality of layers.

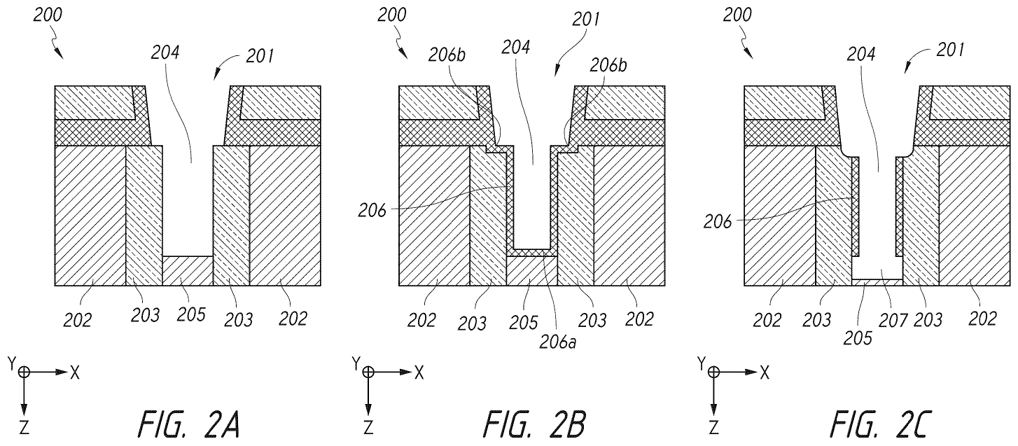

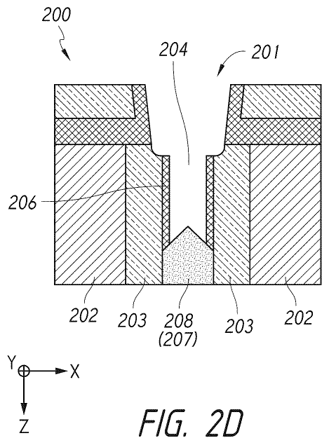

FIGS. 2A-2D depict an example of a dual recess formation process in a bit line contact formation area in at least part of a memory device 200 in a cross-sectional view according to an embodiment of the disclosure. The memory device 200 may be part of the memory device 100 of FIG. 1, and may include regions that correspond to the memory regions 110 and the periphery regions 111 of the memory device 100.

The memory device 200 may include one or more bit line contact (or bitcon) formation areas 201 where one or more bit line contacts or bit line contact structures are formed and one or more cell contact (or cellcon) formation areas 202 where one or more cell contacts or cell contact structures are formed on and/or in a semiconductor substrate. The semiconductor substrate may be a semiconductor wafer or part of a semiconductor wafer. The semiconductor substrate may be a silicon substrate including, for example, monocrystalline silicon.

Each cellcon formation area 202 may be provided in an active region or an active array region. The active region may be defined by an isolation region or may be at least part of an isolation region. The active region may provide an element formation region or may be at least part of an element formation region. In the example, at least one bitcon formation area 201 is provided between the neighboring cellcon formation areas 202.

Referring to FIG. 2A, a first recess 204 is formed in the bitcon formation area 201. In the example, the first recess 204 is provided by etching the bitcon formation area 201 between isolation portions 203, leaving a portion 205 under the first recess 204. The isolation portions 203 are provided on side surfaces of the cell formation areas 202 in preceding processes. The isolation portions 203 may be isolation dielectric portions. The isolation portions or isolation dielectric portions 203 may include, for example, a nitride material, an oxide material, or the like. The first recess 204 may be a trench surrounded by the isolation portions 203 on both sides thereof and the portion 205 at the bottom thereof.

Referring to FIG. 2B, a liner 206 is provided to surfaces of the first recess 204. In the example, the liner 206 is deposited on side surfaces of the first recess 204 and a bottom surface of the first recess 204 (that is an upper surface of the portion 205). The liner 206 may be deposited by using any conventional deposition process in an appropriate manner. The liner 206 may include, for example, an oxide material, or the like.

Referring to FIG. 2C, the liner 206 is etched to open at least part of or substantially all of a bottom portion 206a (see FIG. 2B) of the liner 206. Some other portions, such as step-like portions 206b (see FIG. 2B) of the liner 206 may also be removed during the etching process. This etching process may also be referred to as a punching process. With the punching process, the portion 205 underneath the liner 206 is revealed or exposed to the first recess 204. The etching may be performed by any conventional etching process in an appropriate manner. The etching may be, for example, dry etching or wet etching. Conditions of the etching, such as bias, temperature, and etching rate, may be determined so that at least the part of the bottom portion 206a of the liner 206 is opened or removed. The bottom portion 206a may be completely or substantially completely removed.

A second recess 207 is then formed in the exposed portion 205 by further etching through the open bottom portion of the liner 206. The additional etching may be performed by any conventional etching process in an appropriate manner. The etching may be, for example, dry etching or wet etching. Conditions of the additional etching, such as bias, temperature, and etching rate, may be determined so that the exposed portion 205 is further etched in a vertical direction (that is a direction along Z-axis illustrated in the drawing, for example). The thus-formed second recess 207 together with the first recess 204 makes one continuous recess extending deeper than a depth of the liner 206 in the vertical direction. This process may also be referred to as a dual recess formation process. With the dual recess formation process that provides an additional recess (that is the recess 207 in the example) to an initial recess (that is the recess 204 in the example), an epitaxial growth interface for a subsequent epitaxial growth process is moved further away from the punched interface formed by the previous punching process. This increases a surface area available for epitaxial growth.

Referring to FIG. 2D, after a pre-epitaxial clean process, an epitaxial growth process 208 is performed through the second recess 207 into the first recess 204.

Subsequently, a conductive material is deposited to fill the first and second recesses 204 and 207 to form at least part of the bit line contact structure, which will be electrically connected to one or more bit lines. The conductive material may include metal. The metal may include any conventional metal materials, such as tungsten (W), as appropriate for the bit line contact structure. There may be provided one or more layers including, for example, a layer of titanium nitride (TiN) before the tungsten deposition to form the bit line contact structure.

According to the present embodiment and example, as described, the epitaxial growth interface is moved further away from the punched interface, providing the cleaner and greater surface area available for epitaxial growth in the bitcon formation area. This significantly improves the epitaxial growth margin in the bitcon formation area, especially in the case where a bitcon-cellcon margin needs to be improved. For example, if a liner shrinks a metal bitcon critical dimension, an epitaxial height and growth margin might be reduced. The present embodiment and example with the dual recess formation process in the bitcon formation area improves such epitaxial margin and enables epitaxial growth greater in height (in a vertical direction) and width (in a horizontal direction) in the recess space that expands deeper than the liner. As one example, a pyramid-like shape of a phosphorous rich silicon (SiP) epitaxial growth can be achieved in a significantly greater size than epitaxial growth in a recess space formed by a single recess formation process. This is due to, for example, more available carriers and the increased doped Si volume.

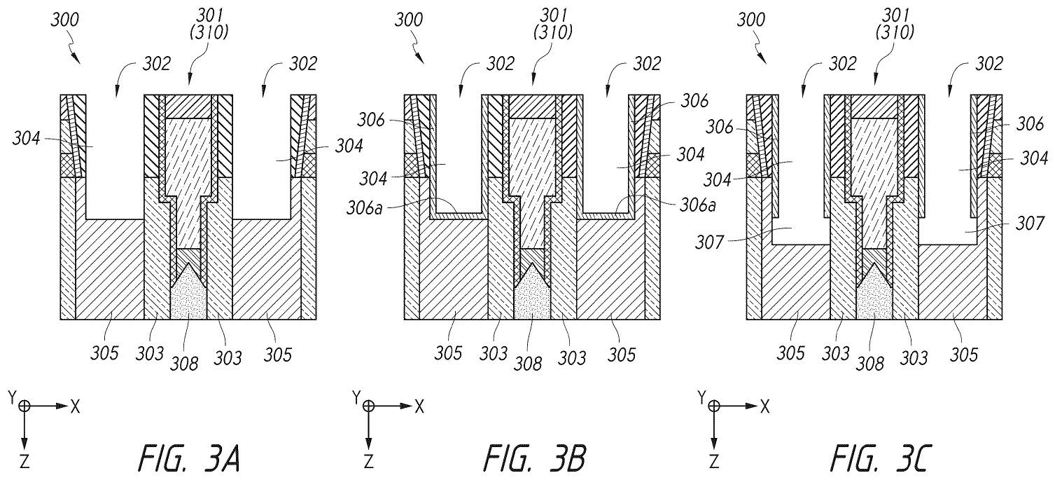

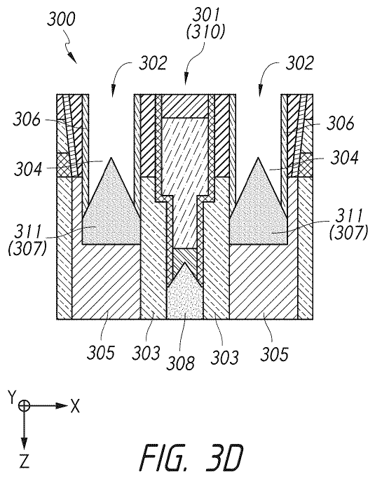

FIGS. 3A-3D depict an example of a dual recess formation process in a cell contact formation area in at least part of a memory device 300 in a cross-sectional view according to an embodiment of the disclosure. The memory device 300 may be part of the memory device 100 of FIG. 1, and may include regions that correspond to the memory regions 110 and the periphery regions 111 of the memory device 100.

The memory device 300 may include one or more bit line contact (or bitcon) formation areas 301 where one or more bit line contacts or bit line contact structures are formed and one or more cell contact (or cellcon) formation areas 302 where one or more cell contacts or cell contact structures are formed on and/or in a semiconductor substrate. The semiconductor substrate may be a semiconductor wafer or part of a semiconductor wafer. The semiconductor substrate may be a silicon substrate including, for example, monocrystalline silicon. The bitcon formation area 301 may correspond to the bitcon formation area 201 of FIGS. 2A-2D (hereinafter collectively referred to as FIG. 2). In the example of FIGS. 3A-3D (hereinafter collectively referred to as FIG. 3), the bitcon formation area 301 includes a bit line contact structure 310. The bit line contact structure 310 is provided in the recess formed by the double recess formation process as described in connection with FIG. 2 after the epitaxial growth 208 (or 308 in FIG. 3).

Each cellcon formation area 302 may be provided in an active region or an active array region. The active region may be defined by an isolation region or may be at least part of an isolation region. The active region may provide an element formation region or may be at least part of an element formation region. In the example, at least one bitcon formation area 301 is provided between the neighboring cellcon formation areas 302, more specifically between isolation portions 303. The isolation portions 303 may be isolation dielectric portions. The isolation portions or isolation dielectric portions 303 may be the isolation portions 203 of FIG. 2.

Referring to FIG. 3A, a first recess 304 is formed in each of the cellcon formation areas 302. In the example, the first recess 304 is provided by etching the cellcon formation area 302, leaving a portion 305 under the first recess 304. The first recess 304 may be a trench like the first recess 204 of FIG. 2.

Referring to FIG. 3B, a liner 306 is provided to surfaces of the first recess 304. In the example, the liner 306 is deposited on side surfaces of the first recess 304 and a bottom surface of the first recess 304 (that is an upper surface of the portion 305). The liner 306 may be deposited by using any conventional deposition process in an appropriate manner. The liner 306 may include, for example, an oxide material, or the like.

Referring to FIG. 2C, the liner 306 is etched to open at least part of or substantially all of a bottom portion 306a (see FIG. 2B) of the liner 306. Some other portions of the liner 306 may also be removed during the etching process. This etching process may also be referred to as a punching process. With the punching process, the portion 305 underneath the liner 306 is revealed or exposed to the first recess 304. The etching may be performed by any conventional etching process in an appropriate manner. The etching may be dry etching or wet etching. Conditions of the etching, such as bias, temperature, and etching rate, may be determined so that at least the part of the bottom portion 306a of the liner 306 is opened or removed. The bottom portion 306a may be completely or substantially completely removed.

A second recess 307 is then formed in the exposed portion 305 by further etching through the open bottom portion of the liner 306. The additional etching may be performed by any conventional etching process in an appropriate manner. The etching may be, for example, dry etching or wet etching. Conditions of the additional etching, such as bias, temperature, and etching rate, may be determined so that the exposed portion 305 is further etched in the vertical direction. The thus-formed second recess 307 together with the first recess 304 makes one continuous recess extending deeper than a depth of the liner 307 in the vertical direction. This process may also be referred to as a dual recess formation process. With the dual recess formation process that provides an additional recess (that is the recess 307 in the example) to an initial recess (that is the recess 304 in the example), an epitaxial growth interface for a subsequent epitaxial growth process is moved further away from the punched interface formed by the previous punching process. This increases a surface area available for epitaxial growth.

Referring to FIG. 3D, in each of the cellcon formation areas 302, after a pre-epitaxial clean process, an epitaxial growth process 311 is performed through the second recess 307 into the first recess 304.

Subsequently, a conductive material is deposited to fill the first and second recesses 304 and 307 to form at least part of the cell contact structure, which will be electrically connected to one or more memory cells. The conductive material may include metal. The metal may include any conventional metal materials suitable for the cell contact structure.

According to the present embodiment and example, as described, the epitaxial growth interface is moved further away from the punched interface, providing the cleaner and greater surface area available for epitaxial growth in the cellcon formation areas. This significantly improves the epitaxial growth margin in the cellcon formation areas, especially in the case where a bitcon-cellcon margin needs to be improved. For example, if a liner shrinks a metal cellcon critical dimension, an epitaxial height and growth margin might be reduced. The present embodiment and example with the dual recess formation process in the cellcon formation areas improves such epitaxial margin and enables epitaxial growth greater in height (in a vertical direction) and width (in a horizontal direction) in the recess space that expands deeper than the liners. As one example, a pyramid-like shape of a phosphorous rich silicon (SiP) epitaxial growth can be achieved in a significantly greater size than epitaxial growth in a recess formed by a single recess formation process. This is due to, for example, more available carriers and the increased doped Si volume.

According to other embodiments, instead of the epitaxial growth, a poly material may be provided to the recess 207 or the recess 307 of FIG. 2D or FIG. 3D to form, for example, a poly plug or at least part of a poly plug. The poly material may be provided by deposition.

The memory device 100, 200, or 300 is one example of the semiconductor device according to the present embodiment. The memory device may be a dynamic random access memory (DRAM). Other examples include, but are not limited to, a static random-access memory (SRAM), a flash memory, an erasable programmable read-only memory (EPROM), a magnetoresistive random-access memory (MRAM), and a phase-change memory. In some embodiments, other examples of the semiconductor device, such as logic ICs (a microprocessor, an application-specific integrated circuit (ASIC) or the like), may also be applicable.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. A method, comprising:
forming a first recess for a bit line contact structure of a semiconductor device;
providing a liner on a surface of the first recess;
etching the linear to open at least part of a bottom of the liner;
forming a second recess under the first recess;
performing an epitaxial growth process through the second recess; and
providing a conductive material to the first and second recesses to form at least part of the bit line contact structure.

2. The method according to claim 1, wherein the second recess is formed to move an epitaxial growth interface further away from the bottom of the liner.

3. The method according to claim 1, wherein the second recess increases a surface available for epitaxial growth.

4. The method according to claim 1, wherein the first recess and the second recess are formed in a bit line contact formation area in a semiconductor substrate.

5. The method according to claim 4, wherein the bit line contact formation area is between cell contact formation areas in the semiconductor substrate.

6. The method according to claim 1, wherein the first recess and the second recess together form a continuous recess deeper than a depth of the liner.

7. The method according to claim 1, further comprising performing a pre-epitaxial clean process before the epitaxial growth process.

8. The method according to claim 1, wherein the conductive material includes metal.

9. A method, comprising:
forming a first recess for a cell contact structure of a semiconductor device;
providing a liner on a surface of the first recess;
etching the linear to open at least part of a bottom of the liner;
forming a second recess under the first recess;
performing an epitaxial growth process through the second recess; and
providing a conductive material to the first and second recesses to form at least part of the cell contact structure.

10. The method according to claim 9, wherein the second recess is formed to move an epitaxial growth interface further away from the bottom of the liner.

11. The method according to claim 9, wherein the second recess increases a surface available for epitaxial growth.

12. The method according to claim 9, wherein the first recess and the second recess are formed in a cell contact formation area in a semiconductor substrate.

13. The method according to claim 12, wherein the cell contact formation area is in an active region.

14. The method according to claim 9, wherein the first recess and the second recess together form a continuous recess deeper than a depth of the liner.

15. The method according to claim 9, further comprising performing a pre-epitaxial clean process before the epitaxial growth process.

16. The method according to claim 9, wherein the conductive material includes metal.

17. A method, comprising:
forming a first bit line contact recess for a bit line contact of a semiconductor device and a first cell contact recess for a cell contact of the semiconductor device;
providing a first liner on a surface of the first bit line contact recess and a second liner on a surface of the first cell contact recess;
etching at least part of a bottom of the first liner and at least part of a bottom of the second liner;
forming a second bit line contact recess under the first bit line contact recess and a second cell contact recess under the first cell contact recess;
performing one or more epitaxial growth processes through the second bit line contact recess and through the second cell contact recess; and
providing one or more conductive materials to the first and second bit line contact recesses to form at least part of the bit line contact and to the first and second cell contact recesses to form at least part of the cell contact.

18. The method according to claim 17, wherein the second bit line contact recess and the second cell contact recess are formed to move epitaxial growth interfaces further away from the bottoms of the first liner and the second liner, respectively.

19. The method according to claim 17, wherein the second bit line contact recess and the second cell contact recess increase surfaces available for epitaxial growth in a bit line contact formation area and a cell contact formation area, respectively.

20. The method according to claim 17, wherein the semiconductor device includes a memory device.
